(19) United States
(12) Patent Application Publication
(10) Pub. No.: US 2003/0219986 A1
(43) Pub. Date: Nov. 27, 2003

(54) Substrate carrier for processing substrates

(75) Inventors: Michael B. Rattner, Santa Clara, CA (US); Rolf A. Guenther, Monte Sereno, CA (US); Jeffrey D. Chinn, Foster City, CA (US)

Correspondence Address: Patent Counsel, Applied Materials, Inc., P. O. Box 450A, Santa Clara, CA, 95052, US

(73) Assignee: Applied Materials, Inc.

(21) Appl. No.: 10/267,824

(22) Filed: Oct. 8, 2002

Related U.S. Application Data
(60) Provisional application No. 60/382,557, filed on May 22, 2002.

(51) Int. Cl. H01L 21/302; H01L 21/461

(52) U.S. Cl. 438/710

(57) ABSTRACT

A substrate carrier for carrying one or more substrates comprises a bottom surface, a top surface opposed to the bottom surface, one or more recesses formed into the top surface, each of the one or more recesses having a support surface that defines a support region for a substrate. The support region is adapted to contact a bottom of the substrate. The support region may have a thickness less than a depth of the one or more recesses. The support region may comprise a porous material to permit thermal fluid to percolate through the support region.

### CROSS REFERENCE TO RELATED APPLICATIONS

This application claims benefit of U.S. provisional patent application serial No. 60/382,557, filed May 22, 2002, which is herein incorporated by reference.

This application is related to copending application Ser. No. ______ filed simultaneously herewith and entitled “Substrate Support Assembly Having an Edge Protector,” (Attorney Docket Number 6984/DISPLAY/AKT) commonly assigned with the present invention.

### BACKGROUND OF THE DISCLOSURE

1. Field of the Invention

The present invention generally relates to chambers for substrate processing and, more particularly, to a substrate carrier that facilitates the processing of substrates of various dimensions in a given chamber.

2. Description of the Related Art

Substrate processing, such as semiconductor wafer processing, is typically practiced in an industrial setting by placing a substrate onto a substrate support or chuck, within a chamber and performing a variety of operations on the substrate. The substrate and substrate support typically are circular shaped, and the substrates currently used typically have a diameter of, for example, about eight inches (200 mm) or about twelve inches (300 mm).

However, in the past, substrate processing was often performed on substrates having smaller diameters, and process equipment of the past included chambers that were designed for processing these smaller substrates. While these process chambers of the past are typically no longer used in high production volume, industrial settings, these older chambers are used, for example, to produce smaller quantities of certain types of microelectronic devices. For example, due to budgetary limitations, universities may purchase older processing equipment that processes, for example, four inch diameter or six inch diameter substrates. Furthermore, it may be necessary for the university to sub-divide the substrate and devices formed thereon into smaller units, for example, dies, to facilitate various testing and further experimentation of the devices formed thereon. The types of material structures and devices that may be formed on these smaller substrates are diverse and include for example, semiconductor materials, optoelectronic devices, microelectromechanical systems and devices (MEMS), among others.

Once a material structure or device, such as a structure to be used in a MEMS device, is formed on small substrate or divided into semiconductor dice, there may be a need for subsequent processing. In particular, there may be a need to perform this subsequent processing in a modern, state-of-the-art, semiconductor processing chamber Unfortunately, most of such state-of-the-art chambers are now only designed to process substrates having a circular cross-section and a diameter of eight inches or twelve inches.

The above problems are compounded for cases in which certain structures, such as MEMS structures, must be formed on the small substrate. This is because the processing of MEMS devices often includes using aggressive etchants to etch deeply into a wafer substrate or in some cases completely through the wafer substrate (i.e. etch-through processing). Etch-through processing is prone to damage the underlying substrate support or chuck, which is a chamber component that is costly to replace.

Furthermore, aggressive etch processing results in the formation of very delicate devices that are highly susceptible to damage during subsequent processing, such as the singulation of the wafer substrate into dies. As a result, it is often desirable to singulate the substrate into dies prior to etch processing to prevent damage to the delicate devices that would otherwise occur from singulation after aggressive etch processing. Singulating the substrate prior to processing however, requires a system capable of etch processing small dies rather than larger wafer substrates.

Therefore, a need exists for a substrate carrier that can be used to convert a conventional semiconductor process chamber into one capable of processing substrates that are smaller than conventional eight inch diameter (200 mm) or twelve inch diameter (300 mm) substrates as well as substrates of varying shapes and dimensions.

### SUMMARY OF THE INVENTION

The invention is a substrate carrier for carrying one or more substrates comprising a bottom surface, a top surface opposed to the bottom surface, one or more recesses formed into the top surface, each of the one or more recesses having a support surface, and a support region between the bottom surface and the support surface. In one embodiment of the invention, the support region has a thickness less than a depth of the one or more recesses. In one embodiment of the invention, the support region may comprise a porous material that may permit thermal fluid (such as helium) to percolate through the support region. In one embodiment of the invention, the one or more recesses are substantially circular. In another embodiment of the invention, the one or more recesses are substantially rectangular.

A method of processing one or more substrates in a processing chamber comprises providing a processing chamber having a substrate support. A substrate carrier having one or more substrates disposed within one or more recesses formed within the substrate carrier is moved into the processing chamber carrier and disposed on a substrate support. A processing operation is then performed within the processing chamber. The processing operation may comprise introducing a process gas into the processing chamber and etching through the substrate to expose the support surface of the carrier to a plasma. An alternate method of processing one or more substrates comprises providing a processing chamber having a substrate carrier disposed on a substrate support. A substrate is moved into the processing chamber and placed onto the support surface of the carrier, and a processing operation is performed within the processing chamber.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic cross-sectional view of a process chamber that can be used for the practice of embodiments of the invention described herein;

FIG. 2 is a schematic close-up, cross-sectional view of a substrate support having a substrate carrier of the present invention thereon;

FIG. 3 is a top view of one embodiment of a substrate carrier that can be used to practice embodiments of the invention described herein;

FIG. 4 is a cross-sectional view of the substrate carrier of FIG. 3;

FIG. 5 is a cross-sectional view of the substrate carrier of FIGS. 3-4, showing additional features thereof;

FIG. 6 is a top view of an alternate embodiment of a substrate carrier having a plurality of recesses thereon;

FIG. 7 is a cross-sectional view of the substrate carrier of FIG. 6;

FIG. 8 is schematic top view of a processing system that can be used for the practice of embodiments of the invention described herein;

FIG. 9 depicts cross-sectional views of a substrate during different stages of an etch-through process sequence;

FIG. 10A depicts a top plan view of an alternate embodiment of a substrate carrier of the present invention; and

FIG. 10B depicts a cross sectional view of the substrate carrier of FIG. 10A.

### DETAILED DESCRIPTION

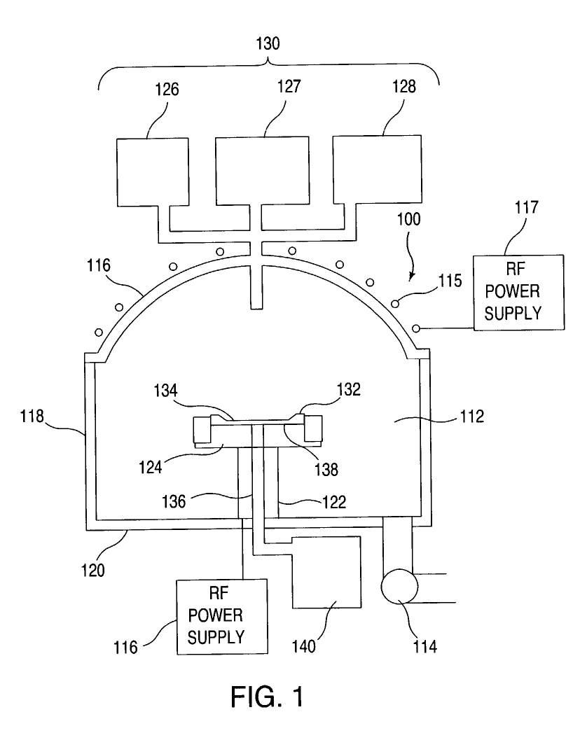

FIG. 1 depicts a schematic, cross-sectional view of an etch processing chamber 100 that can be used for the practice of embodiments of the invention described herein. The etch processing chamber 100 includes a vacuum chamber 112 and a vacuum pump 114 coupled to the vacuum chamber 112. The vacuum chamber 112 is defined by a dome 116 or other form of chamber top, a side wall 118, and a bottom 120. The chamber 112 generally includes a pedestal assembly 123. The pedestal assembly includes a pedestal 122 and a chuck 124, such as an electrostatic chuck, atop the pedestal 122. The chuck 124 is a conventional chuck typically formed to accommodate substrates having a circular cross section that may be about eight inches (200 mm) or about twelve inches (300 mm) in diameter. A high frequency power source 116 such as a radio frequency (RF) power source may be coupled to the pedestal 122 in order to capacitively couple RF power to a substrate (not shown) to form a negative bias on the substrate that facilitates etching. A second RF power source 117 may be coupled to at least one antenna 115, to control the plasma density within the chamber 112. An example of such an etch processing chamber 100 is the Decoupled Plasma System (DPS I and DPS II) chamber, commercially available from Applied Materials, Inc., Santa Clara, Calif.

A substrate carrier 132 useful for adapting the etch processing chamber 100 for processing substrates of various shapes and sizes is positioned atop the chuck 124. One or more substrates (not shown) are placed into one or more recesses 154 formed in the substrate carrier 132.

A port 136 may be formed through the pedestal 122 to a top surface 138 of the chuck 124. A thermal fluid, such as an inert gas, flows from a backside gas source 140 to the top surface 138 of the chuck 124. The thermal fluid may be, for example, helium.

The vacuum pump 114 draws a vacuum inside the chamber 112 and process gases are pumped from one or more gas sources 130 into the chamber 112. In FIG. 1, three gas sources 126, 127, 128 are shown by way of example. The process gases may comprise, for example, a fluorinated gas, such as silicon tetrafluoride (SiF₆), hydrogen fluoride (HF), nitrogen trifluoride (NF₃), xenon difluoride (XeF₂), among other fluorinated gases. The process gases may also comprise nonfluorinated gases, for example, methanol (CH₃OH), water vapor (H₂O), among other non-fluorinated gases. The applied RF power ignites one or more of the process gases into a plasma within the chamber 112 in order to enhance etching of the one or more substrates and/or material layers thereon. Process gases introduced into the chamber 112 from the gas sources 130 are directed to one or more substrates on the substrate carrier 132 where they may etch various materials on the one or more substrates. In one embodiment of the invention, at least one of the process gases, such as, for example, one of the fluorinated gases, is excited into a plasma state in a remote plasma chamber (not shown) prior to entering the chamber 112 and thereafter directed towards the one or more substrates.

Substrate carrier

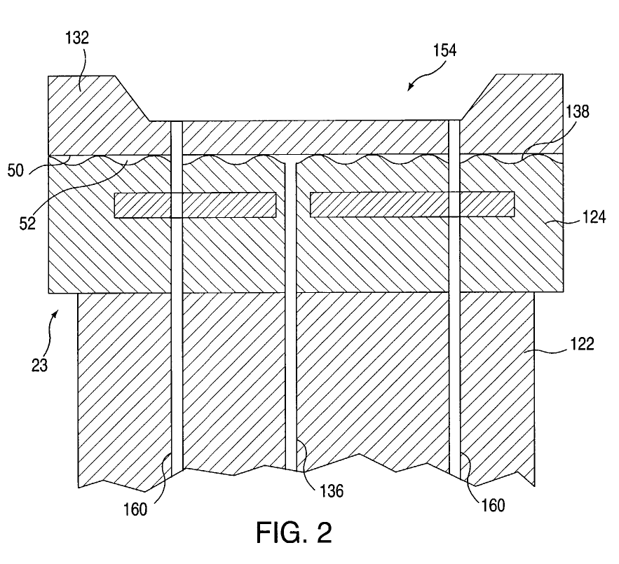

FIG. 2 illustrates a close-up cross-sectional view of a substrate carrier 132 that may be used to practice embodiments of the invention described herein. The substrate carrier 132 is supported by a pedestal assembly 123 that generally comprises the pedestal 122 and the chuck 124. The chuck 124 sits atop the pedestal 122, and the pedestal 122 and the chuck 124 may have a port 136 therethrough for transporting a thermal fluid to the top surface 138 of the chuck 124. While FIG. 2 depicts one central port, there may be a plurality of ports 136 configured in various arrangements so as to transport the thermal fluid to the top surface 138 of the chuck 124. The pedestal 122 and the chuck 124 may include one or more channels 160 through which lift pins (not shown) may be elevated in order to facilitate raising and lowering a substrate within the chamber 112. The channels 160 may optionally extend through the substrate carrier 132. In one embodiment of the invention the substrate carrier 132 is secured to the chuck 124 by electrostatic force as described below. In another embodiment of the invention, the substrate carrier 132 is secured to the chuck 124 by various means, such as, for example, bolts or other mechanical fasteners.

The substrate carrier 132 has a bottom surface 150 that generally contacts the top surface 138 of the chuck 124. A plurality of channels or interstitial spaces 152 (exaggerated in size for clarity) located between the top surface 138 of the chuck 124 and the bottom surface 150 of the substrate carrier 132 transport thermal fluid such that thermal fluid contacts at least a portion of the bottom surface 150 of the substrate carrier 132. The substrate carrier 132 has one or more recesses 154 to facilitate the carrying of one or more substrates (not shown).

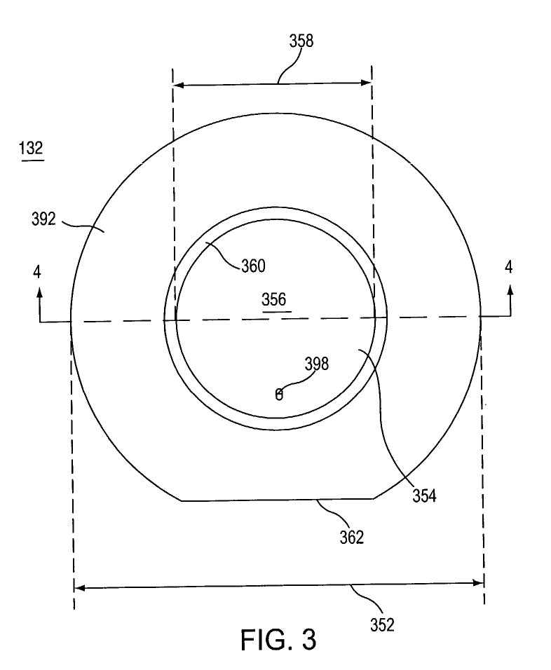

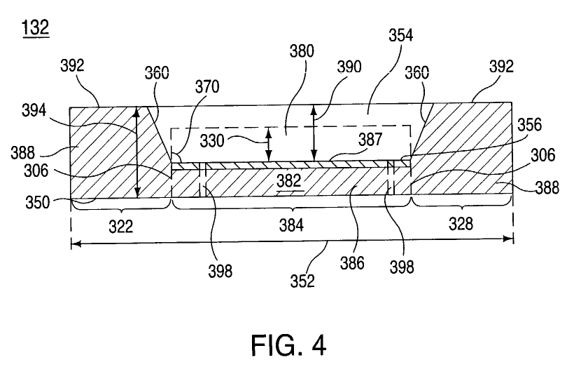

FIG. 3 depicts a top view of one embodiment of the substrate carrier 132, and FIG. 4 depicts a cross-sectional view of the substrate carrier 132 of FIG. 3 with the cross-section taken along line 4-4 of FIG. 3. In general, the substrate carrier 132 has a size and shape that enables a conventional substrate handling robot to carry the substrate carrier 132 and substrate(s) disposed therein, in and out of the chamber 112. The substrate carrier 132 includes a bottom surface 350 that is generally formed to fit on a conventional substrate support such as the substrate support 123 of FIG. 2. The bottom surface 350 may be substantially circular with a diameter 352. The substrate carrier 132 includes a recess 354 that is defined by a support surface 356 and a containment surface 360. Referring to FIG. 3, the support surface 356 is substantially circular. The support surface 356 may have a diameter 358 of about, for example, 4 inches or about 6 inches and may thereby accommodate substrates having a similar diameter. Rays parallel to the containment surface 360 and the support surface 356 generally define an angle 370 that may be about 90 degrees or greater. i.e., the containment surface 360 is sloped. In one embodiment of the invention, the angle 370 is about 135 degrees to facilitate placement of a substrate 380 (shown in phantom) having a thickness 330 within the recess 354 of the substrate carrier 132.

The substrate carrier 132 includes a support region 382 that has a cross-section bounded by the support surface 356, a portion 384 of the bottom surface 350, and boundary surfaces 306 (shown in phantom). The support region 382 has a thickness 386 that is generally small enough to promote rapid heat transfer from the pedestal 122 and the chuck 124 to the substrate 380. The thickness 386 of support region 382 may be less than a depth 390 of the recess 354. The thickness 386 of the support region 382 may be less than the thickness 330 of the substrate 380 placed within the recess 354. The thickness 386 of the support region 382 is generally small enough to promote rapid thermal transfer across the thickness 386. Similarly, the thickness 386 of the support region 382 is generally large enough to provide mechanical support for the substrate 380 and to allow the substrate carrier 132 to withstand the stresses of both processing and handling of the substrate carrier 132 without cracking or otherwise being damaged. In one embodiment of the invention, the thickness 386 of the support region 382 is in the range of about 0.025 centimeters to about 0.13 centimeters.

The substrate carrier 132 also includes outer regions 388 adjacent to the support region 382. The outer regions 388 are generally bounded by a top surface 392 that may be substantially parallel to the bottom surface 350, an edge surface 320, the containment surface 360, a portion 322 of the bottom surface 350, and the boundary surfaces 306. The top surface 392 may have a flat portion 362, as shown in FIG. 3 such that the substrate carrier 132 has a periphery that matches a flatted wafer substrate. Alternatively, the periphery may have a notch to match the periphery of a notched wafer substrate. The outer regions 388 typically have a thickness 394 that is sufficiently large such that the substrate 380 does not extend above the top surface 392. The outer regions 388 typically have a thickness 394 that is sufficiently small such that the substrate carrier 132 does not interfere with the function of other components within the chamber 112, e.g. slit valve, robot arm, lift mechanism and the like. The thickness 394 of the outer regions 388 may be, for example, in the range of about 0.25 centimeters to about 0.65 centimeters.

The support region 382 generally comprises a material that is resistant to degradation when exposed to various environmental conditions within the chamber 112. These environmental conditions may be, for example, temperatures in excess of about 200 degrees Celsius, exposure to high frequency power of up to about 7 watts per square centimeters, and damage from contact with corrosive gases such as fluorinated gases, including hydrogen fluoride (HF). The support region 382 generally comprises a dielectric material that is capable of maintaining an electrostatic charge on the support surface 356. In this manner, the substrate carrier 132 and the substrate 380 may be held in place on the underlying electrostatic chuck 124. The support region 382 may comprise a material with high thermal conductivity.

In one embodiment of the invention, the support region 382 comprises a ceramic material, such as, for example, silicon carbide, aluminum oxide, silicon nitride, or combinations thereof. The ceramic material may be formed by various methods, such as, for example, hot isostatic pressing, dry-pressing, among other methods known to the art of ceramics processing. In one embodiment of the invention, the ceramic material is formed by fabricating a porous, graphite-based material and partially or completely reacting the graphite-based material to form a silicon carbide material. Products made by this process are available from Poco Graphite Inc., of Decatur, Tex.

In another embodiment of the invention, the support region 382 comprises a metallic material having a dielectric coating 387 formed on the support surface 356. The dielectric coating 387 may comprise, for example, an oxide, a nitride, or other dielectric material. The support region 382 and the outer regions 388 may be formed by pressing a single piece of ceramic material into a desired shape. Alternatively, the support region 382 and the outer regions 388 may be formed as separate units and later joined together by sintering the separate units together or other joining methods known to the art of ceramics or metals processing, such as welding, diffusion bonding. among other joining methods.

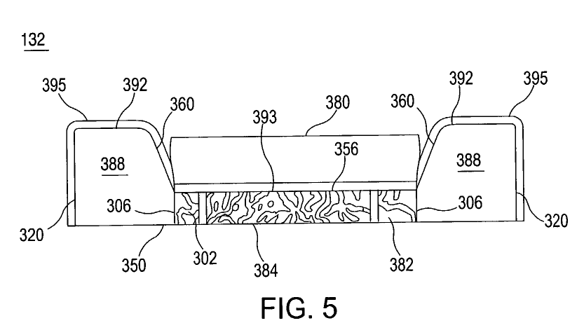

FIG. 5 depicts the cross-sectional view of the substrate carrier 132 of FIG. 4, showing additional features thereof. The support region 382 may comprise a porous material having pores 302 (exaggerated in size for clarity). The porous material may have open porosity, i.e. porosity that is open to an outer surface such as the support surface 356 or the bottom surface 350. In one embodiment of the invention, the support region 382 comprises a material with an open porosity in the range of about 1% to about 20% by volume. The porosity of the support region 382 may be such that a thermal fluid or gas may percolate from the bottom surface 350, through the pores 302 in the support region 382, to the support surface 356. The thermal fluid is retained beneath the substrate 380 and in the pores 302 to enhance thermal conductivity to and from the substrate 380.

Typically the porosity within the support region 382 is such that no direct line-of-sight path exists between the support surface 356 and the bottom surface 384. In other words, the pores 302 are sufficiently tortuous and windy such that the length of the pores 302 are considerably greater than the thickness 386 of the support region 382. This property of the pores 302 is particularly beneficial for the case in which a plurality of holes must be etched through the substrate 380. Because some holes may be etched through areas of the substrate 380 prior to other holes, an etch process may be intentionally designed to “over-etch” the substrate, 380. Once the substrate 380 is etched through, aggressive etchant gas that may be traveling, for example, perpendicular to the substrate 380 would be available to travel through the pores 302 to react with, and perhaps damage, the underlying chuck 124. By having tortuous and windy pores 302 with no line-of-sight distance between the bottom surface 350 and the support surface 356, the likelihood of the etchant gas reaching the chuck 124 is reduced or eliminated.

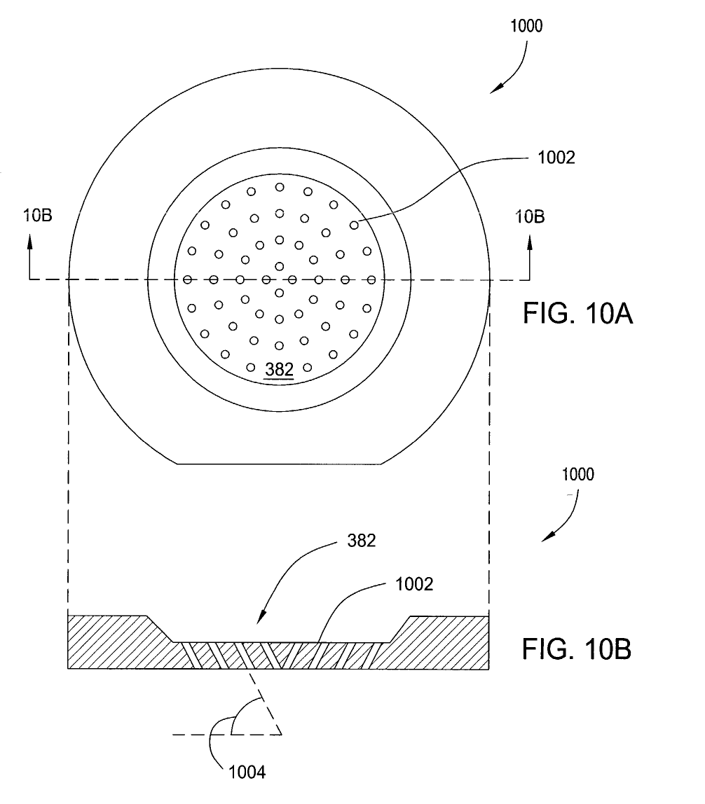

In another embodiment of the invention shown in a top plan view in FIG. 10A and a cross-section view in FIG. 10B, the entire carrier 1000 or only the support region 382 may be fabricated of aluminum. The aluminum is generally anodized. The support region 382 comprises a plurality of channels 1002 drilled through the support region 382 on an angle. The angle 1004 is defined by the thickness of the support region 382 and the need to ensure that the channels do not provide a line of site path through the support region. As such, the top of the angled channel is offset from the bottom of the angled channel such that a vertical path (perpendicular to the surface of the support region) is not possible. Such an angle prevents etchant gases, that generally travel in a path that is perpendicular to the wafer surface, from impacting the surface of the underlying chuck. The channels are sized to enable backside cooling gas (typically helium) to flow from the chuck surface to the backside surface of the substrate. The channel diameter is exaggerated in FIG. 10A and 10B for clarity.

The support region 382 of any of the forgoing embodiments of the carrier may comprise an indicator 393 for determining when the substrate 380 within the recess 354 has been etched through. The indicator 393 may be a chemical or material that is embedded within the support region 382 or deposited on the support surface 356. For those embodiments of the invention in which the dielectric coating 387 is formed on the support surface 356, the indicator 393 may be deposited on the dielectric coating 387. The indicator 393 reacts with, for example, an etchant gas to form a product such as a gaseous product. The product may be detected by an endpoint detection system (not shown) that may include, for example, optical or chemical sensors for detecting the presence of the product generated by the indicator 393 and the etchant gas, thereby determining the point of completion of the etch-through process.

The outer regions 388 may comprise a ceramic material. In one embodiment of the invention, the outer regions 388 comprise a porous material as described above with reference to support region 382. In this embodiment of the invention, the outer regions 388 may have a coating 395 formed on the top surface 392 as well as on the containment surface 360. The composition of the coating 395 may comprise a material that is chemically resistant to process gases that are introduced into the chamber 112. For example, for embodiments of the invention in which a fluorinated gas, such as hydrogen fluoride (HF), is introduced into the chamber 112, the coating 395 may comprise, for example, aluminum oxide (Al₂O₃), sapphire, a perfluoroalkoxy material, a polytetrafluoroethylene material (e.g. Teflon® available from E. I. du Pont de Nemours and Company of Wilmington, Del.), among other materials. The coating 395 generally improves the durability of the outer regions 388 by, for example, protecting the outer regions 388 from degradation from process gases. In an alternate embodiment of the invention, the outer regions 388 may comprise a densified material with less open porosity than the support region 382.

In one embodiment of the invention, the substrate carrier 132 includes optional channels 398 formed through the support region 382. The optional channels 398 allow lift pins (not shown) to move through the substrate carrier 132 to facilitate the raising and lowering of the substrate 380 within the chamber 112.

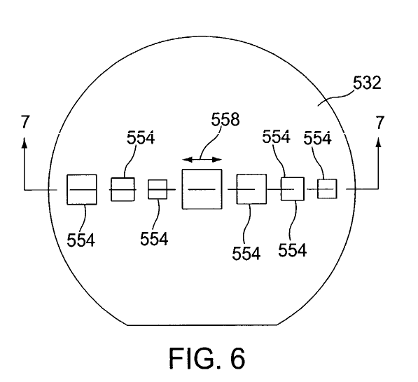

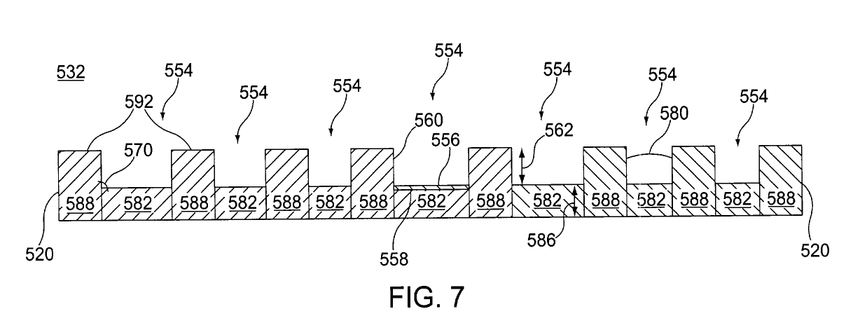

FIGS. 3-5 depict a substrate carrier 132 having the recess 354 that is designed to accommodate a single, substantially-circularly shaped substrate. Alternatively, a substrate carrier may have multiple recesses or non-circular recesses (e.g. rectangular or square recesses). FIG. 6 depicts a top view of one embodiment of the substrate carrier 532, and FIG. 7 depicts a cross-sectional view of the substrate carrier 532 of FIG. 6 with the cross-section taken along line 7-7 of FIG. 6. The substrate carrier 532 has a plurality of square recesses 554 (a specific type of rectangular recess). The square recesses 554 are generally defined by a bottom surface 556 and containment surfaces 560.

Each of the square recesses 554 has a length 558. The length 558 may be the same for all of the square recesses 554, or the length 558 may vary amongst the various square recesses 554 on the substrate carrier 532. The length 558 may be in the range of, for example, about 10 millimeters to about 20 millimeters. The square recesses 554 generally have a depth 562 that is greater than a thickness 586 of a support region 586. The depth 562 may be, for example, about 0.025 centimeters to about 0.13 centimeters. Rays parallel to the containment surface 560 and the bottom surface 556 generally define an angle 570 that may be, for example, at least about 100 degrees. The square recesses 554 each accommodate a substrate (such as substrate 580 shown in phantom in FIG. 7) that are generally square when viewed from the top. The substrate 580 may be, for example, a semiconductor die.

The substrate carrier 532 generally includes support regions 582 and the outer regions 588. The composition, porosity, and other properties of the support regions 582 and the outer regions 588 may be similar to those of the corresponding support regions 382 and the outer regions 388 of the substrate carrier 132 detailed in FIG. 5. One or more surfaces, such as a top surface 592, an edge surface 520, and containment surfaces 560 may have a protective coating (such as the coating 395 shown in FIG. 5) formed thereon to protect the surfaces from, for example, process gases that may otherwise come into contact with said surfaces.

Method of Using the Substrate Carrier

The substrate carrier of the present invention may be used to facilitate the processing of one or more substrates of varying dimensions and shapes in a processing chamber that is designed to process conventional larger wafer substrates. The conventional wafer substrates may be semiconductor wafers, having a substantially circular shape and a diameter that may be about eight inches (200 millimeters) or about twelve inches (300 millimeters).

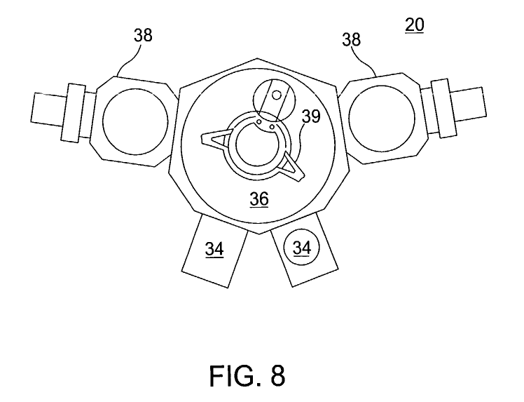

FIG. 8 depicts a processing system 20 in which substrates are processed. Processing system 20 includes a plurality of process chambers 38 and a central transfer chamber 36. Inside each of the process chambers 38, substrates may be subjected to a variety of processing operations such as, for example, thin film deposition processing, etching and etch-through processing, oxidation, thermal processing, lithographic processing, among other processing operations.

In general one or more substrates are provided to a transfer chamber 36 from a load lock chamber 34. In one embodiment, a substrate carrier, such as the substrate carrier 132 or the substrate carrier 532, having one or more substrates placed within recesses therein, is provided to a substrate handling robot 39. The substrate handling robot 39 moves the substrate carrier between the load lock chamber 34 and the processing chamber 38. Referring to FIGS. 1 and 8, within the processing chamber, lift pins may be raised through the channels 160 within the pedestal 122 and the chuck 124. The substrate carrier is transferred onto the lift pins from the substrate handling robot, and the pedestal assembly 123 is raised such that the substrate carrier is directed onto the chuck 124. The substrate carrier may thereafter be secured onto the chuck by an electrostatic chucking force. The backside gas (thermal fluid) is then applied to the bottom surface 350 of the substrate carrier 132. The thermal fluid percolates to the support surface 356 of the recess 354 to insure thermal conductivity between the substrate 380 and the chuck 124. One or more processing operations, such as, for example, etch-through operations, may be performed on the substrate or material layers thereon. In this embodiment of the invention, a substrate carrier without channels such as the optional channels 398 formed through the support region 382 may be used. After performing the one or more processing operations within the processing chamber 38, the substrate carrier and one or more substrates thereon are removed from the processing chamber 38 by the substrate handling robot 39.

In an alternate embodiment of the invention, a substrate is provided to the substrate handling robot 39. The substrate handling robot 39 moves the substrate between the load lock chamber 34 and the processing chamber 38. The processing chamber 38 may be, for example, an etch processing chamber, such as the chamber 112 of FIG. 1. Within the processing chamber 38, lift pins (not shown) may be raised through the channels 160 within the pedestal 122, the chuck 124, and the substrate carrier 132. The substrate is transferred onto the lift pins from the substrate handling robot 39, and the substrate is directed into one or more recesses such as the recess 354 shown in FIG. 4 or the recesses 554 shown in FIG. 6 in the substrate carrier. The substrate may be held in position by providing, for example, an electrostatic chucking force. One or more processing operations, such as, for example, etch-through operations, may be performed on the substrate or material layers thereon. After performing the one or more processing operations, the substrate is removed from the processing chamber 39 by the substrate handling robot 39.

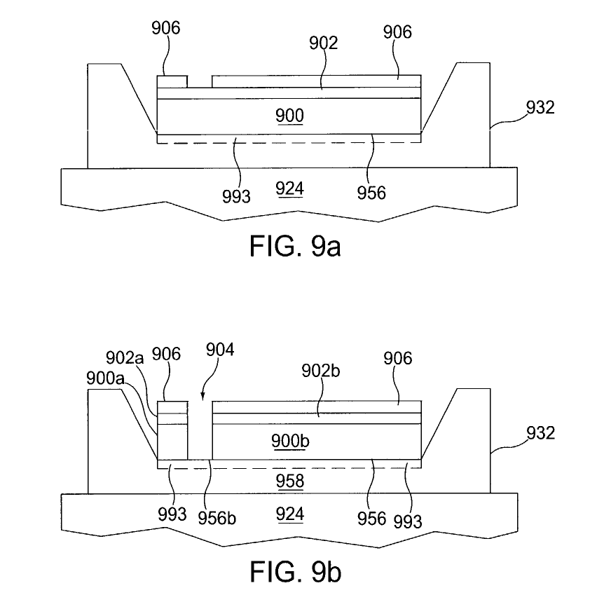

In one embodiment of the invention, as depicted in FIG. 9, a process gas such as, for example, silicon hexafluoride (SiF₆), hydrogen fluoride (HF), nitrogen trifluoride (NF₃), xenon difluoride (XeF₂), is provided to a processing chamber such as chamber 112 of FIG. 1. The process chamber includes a substrate support 924. The substrate support 924 may comprise, for example a pedestal, such as the pedestal 122 and a chuck such as the chuck 124. A substrate carrier 932 and a substrate 900 rests on a support surface 956 of substrate carrier 932, as shown in FIG. 9a. The substrate 900 may be, for example, a silicon die or a silicon wafer. A material layer 902, such as an oxide may be provided atop the substrate 900. An etch resist 906 is formed and patterned on the material layer 902 using conventional photoresist processing methods. The process gas etches portions of the material layer 902 and portions of the substrate 900 that are not protected by the etch resist 906. The etching continues until an endpoint, as indicated in FIG. 9b, a time at which the process gas etches through the material layer 902 and the substrate 900 creating two substrate regions 900a and 900b as well as two material layer regions 902a and 902b. An opening 904 thus formed uncovers a portion 956b of the support surface 956. The substrate carrier 932 protects the substrate support 924 from being etched by the process gas.

The endpoint may be determined by using, for example, an endpoint detection system that includes, for example, optical and/or chemical sensors to determine whether the portion 956b of the support surface 956 has been uncovered and no further etching is desired. In one embodiment of the invention, an indicator 993 (shown in phantom) located within or deposited on a support region 956 reacts with the process gas and produces a product that may be detected by the endpoint detection system.

While the foregoing is directed to the preferred embodiment of the present invention, other and further embodiments of the invention may be devised without departing from the basic scope thereof, and the scope thereof is determined by the claims that follow.

1. A substrate carrier for carrying one or more substrates comprising:
a bottom surface;
a top surface opposed to the bottom surface; and
one or more recesses formed into the top surface, each of the one or more recesses having a support surface that defines a support region for a substrate, where said support region is adapted to contact a bottom of the substrate.

2. The substrate carrier of claim 1 wherein the support region is between the bottom surface and the support surface, and wherein the support region has a thickness less than a depth of the one or more recesses.

3. The substrate carrier of claim 1 wherein the support region comprises a porous material.

4. The substrate carrier of claim 3 wherein the porous material has an open porosity between about 1 percent and about 20 percent.

5. The substrate carrier of claim 3 wherein the porous material comprises a material selected from the group consisting of silicon carbide, silicon nitride, aluminum oxide, a metallic material, and combinations thereof.

6. The substrate carrier of claim 3 wherein the porous material has sufficient open porosity to permit thermal fluid to percolate from the bottom surface to the support surface.

7. The substrate carrier of claim 1 wherein the support region has a thickness between about 0.025 centimeters and about 0.13 centimeters.

8. The substrate carrier of claim 1 wherein the support region comprises an indicator for determining when the substrate has been etched through.

9. The substrate carrier of claim 1 wherein one of the one or more recesses have a substantially circular support surface.

10. The substrate carrier of claim 1 further comprising a plurality of channels through the support region, where said channels are angled.

11. The substrate carrier of claim 1 wherein one of the one or more recesses have a substantially rectangular support surface.

12. The substrate carrier of claim 4 further comprising outer regions bounded by the top surface and the bottom surface and coupled to the support region, wherein the outer regions comprise a material having an open porosity less than the open porosity of the porous material in the support region.

13. A substrate carrier for carrying one or more substrates comprising:
a bottom surface:
a top surface opposed to and substantially parallel to the bottom surface;
an edge surface circumscribing the top surface and the bottom surface;
one or more recesses formed into the top surface, the one or more recesses having a support surface that defines a support region for a substrate, wherein said support region is adapted to contact a bottom of the substrate, and wherein the support surface has an area smaller than an area of the bottom surface, and the support surface is substantially parallel to the bottom surface and the top surface; and
a containment surface being sloped and connecting the top surface to the support surface.

14. The substrate carrier of claim 13 wherein the support region is between the bottom surface and the support surface, and wherein the support region has a thickness less than a depth of the one or more recesses.

15. The substrate carrier of claim 13 wherein the support region comprises a porous material.

16. The substrate carrier of claim 15 wherein the porous material has an open porosity between about 1 percent and about 20 percent.

17. The substrate carrier of claim 15 wherein the porous material comprises a material selected from the group consisting of silicon carbide, silicon nitride, aluminum oxide, a metallic material, and combinations thereof.

18. The substrate carrier of claim 15 wherein the porous material has sufficient open porosity to permit thermal fluid to percolate from the bottom surface to the support surface.

19. The substrate carrier of claim 13 wherein the support region has a thickness between about 0.02 centimeters and about 0.13 centimeters.

20. The substrate carrier of claim 13 wherein the support region comprises an indicator for determining when the substrate has been etched through.

21. The substrate carrier of claim 13 wherein one of the one or more recesses have a substantially circular support surface.

22. The substrate carrier of claim 13 wherein one of the one or more recesses have a substantially rectangular support surface.

23. The substrate carrier of claim 16 further comprising outer regions bounded by the top surface and the bottom surface and coupled to the support region, wherein the outer regions comprise a material having an open porosity less than the open porosity of the porous material in the support region.

24. The substrate carrier of claim 13 wherein one or more surfaces selected from the group consisting of the top surface, the edge surface, the containment surface, and combinations thereof have a protective coating formed thereon.

25. The substrate carrier of claim 24 wherein the protective coating comprises a material selected from the list consisting of alumina, sapphire, a polytetrafluoroethylene material, a perfluoroalkoxy material, and combinations thereof.

26. A method of processing one or more substrates in a processing chamber, comprising:
providing a processing chamber having a substrate carrier disposed on a substrate support, wherein the substrate carrier comprises a bottom surface, a top surface opposed to the bottom surface, one or more recesses formed into the top surface, each of the one or more recesses having a support surface that defines a support region between the bottom surface and the at least one support surface;
moving a substrate into the processing chamber and placing the substrate onto the support surface; and
performing a processing operation within the processing chamber.

27. The method of claim 26 wherein the substrate has a thickness greater than a thickness of the support region.

28. The method of claim 26 further comprising providing a thermal fluid to the bottom surface of the substrate support and allowing the thermal fluid to percolate from the bottom surface of the substrate carrier to the support surface of the substrate carrier.

29. The method of claim 26 wherein the processing operation comprises introducing a process gas into the processing chamber and etching through the substrate to expose the support surface.

30. The method of claim 29 wherein the process gas comprises a gas selected from the group consisting of silicon hexafluoride (SiF₆), hydrogen fluoride (HF), nitrogen trifluoride (NF₃), xenon difluoride (XeF₂), and combinations thereof.

31. The method of claim 26 wherein the processing operation comprises igniting a process gas into a plasma.

32. A method of processing one or more substrates in a processing chamber, comprising:
providing a processing chamber having a substrate support;
moving a substrate carrier into the processing chamber, wherein the substrate carrier comprises a bottom surface, a top surface opposed to the bottom surface, one or more recesses formed into the top surface, the one or more recesses each having a support surface, and a support region between the bottom surface and the at least one support surface; and
performing a processing operation within the processing chamber.

33. The method of claim 32 wherein one or more substrates having a thickness greater than a thickness of the support region are disposed within the one or more recesses.

34. The method of claim 32 further comprising providing a thermal fluid to the bottom surface of the substrate support and allowing the thermal fluid to percolate from the bottom surface of the substrate carrier to the support surface of the substrate carrier.

35. The method of claim 32 wherein the processing operation comprises introducing a process gas into the processing chamber and etching through the substrate to expose the support surface.

36. The method of claim 35 wherein the process gas comprises a gas selected from the group consisting of silicon tetrafluoride (SiF₆), hydrogen fluoride (HF), nitrogen trifluoride (NF₃), xenon difluoride (XeF₂), and combinations thereof.

37. The method of claim 34 wherein the processing operation comprises igniting a process gas into a plasma.
